(19) United States
(12) Patent Application Publication
(10) Pub. No.: US 2018/0061752 A1
(43) Pub. Date: Mar. 1, 2018

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Shih-Che Huang, Chiayi City (TW); Ching-Li Yang, Ping-Tung Hsien (TW); Yu-Cheng Tung, Kaohsiung City (TW); Yu-Tsung Lai, Tainan City (TW); Chih-Sheng Chang, New Taipei City (TW)

(21) Appl. No.: 15/271,221

(22) Filed: Sep. 20, 2016

(30) Foreign Application Priority Data
Aug. 24, 2016 (TW) 105127007

(51) Int. Cl. H01L 23/522; H01L 23/528; H01L 49/02; H01L 23/532; H01L 21/02; H01L 21/768

(52) U.S. Cl. CPC H01L 23/5223; H01L 23/5283; H01L 28/60; H01L 21/76877; H01L 21/02183; H01L 21/02186; H01L 21/76843; H01L 23/53295

(57) ABSTRACT

A method for fabricating semiconductor device is disclosed. First, a substrate is provided, and a capacitor is formed on the substrate and a hard mask on the capacitor, in which the capacitor includes a bottom electrode, a capacitor dielectric layer, and a top electrode. Next, a protective layer is formed on the sidewalls of the top electrode and the bottom electrode, in which the protective layer includes metal oxide.

### BACKGROUND OF THE INVENTION

### 1. Field of the Invention

The invention relates to a capacitor and fabrication method thereof, and more particularly to a metal-insulator-metal (MIM) capacitor and fabrication method thereof.

### 2. Description of the Prior Art

In semiconductor manufacturing processes, metal capacitors formed of metal-insulator-metal (MIM) are widely used in the design of ultra large scale integrations (ULSI). Because a MIM capacitor has low resistance and low parasitic capacitance, and has no problems in shifts of depletion induced voltage, MIM capacitors have become the main structure used for metal capacitors. It is therefore important to develop a MIM capacitor that includes copper electrodes with low resistance.

With the increasing complexity of integrated circuits, the multilevel interconnect process has become the typical method used in semiconductor integrated circuit fabrication. To satisfy the requirements for high integration and high speed in integrated circuits (ICs), especially in a deep sub-micro (<0.18 μm) semiconductor process, copper (Cu) dual damascene process is becoming more widely used as a standard process in forming interconnection lines within the inter-metal dielectric layer of low dielectric constant (low k) materials. Since copper has the traits of having both low resistance and low electromigration resistance, low k materials are useful in improving the RC delay effect of metal interconnections. Consequently, how to integrate copper fabrication processes to fabricate MIM capacitors and internal metal wires with low resistance has become a key research topic in this field.

### SUMMARY OF THE INVENTION

According to a preferred embodiment of the present invention, a method for fabricating semiconductor device is disclosed. First, a substrate is provided, and a capacitor is formed on the substrate and a hard mask on the capacitor, in which the capacitor includes a bottom electrode, a capacitor dielectric layer, and a top electrode. Next, a protective layer is formed on the sidewalls of the top electrode and the bottom electrode, in which the protective layer includes metal oxide.

According to another aspect of the present invention, a semiconductor device is disclosed. The semiconductor device includes: a capacitor on a substrate, in which the capacitor includes a bottom electrode, a capacitor dielectric layer, and a top electrode; a hard mask on the capacitor; and a protective layer on the sidewalls of the top electrode and the bottom electrode, in which the protective layer includes metal oxide.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a method for fabricating a MIM capacitor according to a preferred embodiment of the present invention.

FIG. 2 illustrates a structural view of a semiconductor device according to an embodiment of the present invention.

FIG. 3 illustrates a structural view of a semiconductor device according to an embodiment of the present invention.

FIG. 4 illustrates a structural view of a semiconductor device according to an embodiment of the present invention.

FIG. 5 illustrates a structural view of a semiconductor device according to an embodiment of the present invention.

FIG. 6 illustrates a structural view of a semiconductor device according to an embodiment of the present invention.

FIG. 7 illustrates a structural view of a semiconductor device according to an embodiment of the present invention.

FIG. 8 illustrates a structural view of a semiconductor device according to an embodiment of the present invention.

FIG. 9 illustrates a structural view of a semiconductor device according to an embodiment of the present invention.

### DETAILED DESCRIPTION

Referring to FIG. 1, FIG. 1 illustrates a method for fabricating a MIM capacitor according to a preferred embodiment of the present invention. As shown in FIG. 1, a substrate 12, such as a semiconductor substrate including silicon substrate, epitaxial silicon substrate, silicon carbide (SiC) substrate, or silicon-on-insulator (SOI) substrate is provided. At least an active device could be disposed on the substrate 12, in which the active device could include metal-oxide semiconductor (MOS) transistor, oxide semiconductor field effect transistor (OS FET), fin field effect transistor (FinFET), or other active devices.

In this embodiment, three MOS transistors 14 are disposed on the substrate 12, in which each of the MOS transistors 14 includes a gate structure 16 on the substrate, a spacer 18 adjacent to the sidewalls of the gate structure 16, and a source/drain region 20 in the substrate 12 adjacent to two sides of the spacer 18. Additionally, each of the MOS transistors 14 could also include standard MOS elements such as silicide (not shown) and epitaxial layer (not shown), and the details of which are not explained herein for the sake of brevity.

In this embodiment, the spacer 18 could be selected from the group consisting of silicon nitride, silicon oxide, silicon oxynitride, and silicon carbon nitride, and the gate structure 16 could be a polysilicon gate made of polysilicon or a metal gate depending on the demand of the process. It should also be noted that even though three MOS transistors 14 are disposed on the substrate 12, the number and composition of the MOS transistors 14 are not limited to the ones disclosed in this embodiment.

For instance, if the gate structure 16 were to be a metal gate, it would further include elements such as a high-k dielectric layer, a work function metal layer, and a low resistance metal layer. Preferably, the high-k dielectric layer is selected from dielectric materials having dielectric constant (k value) larger than 4. For instance, the high-k dielectric layer may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZr₃, PZT), barium strontium titanate (BaₓSr₁₋ₓTiO₃, BST) or a combination thereof.

The work function metal layer is formed for tuning the work function of the later formed metal gates to be adaptable in an NMOS or a PMOS. For an NMOS transistor, the work function metal layer having a work function ranging between 3.9 eV and 4.3 eV may include titanium aluminide (TiAl), zirconium aluminide (ZrAl), tungsten aluminide (WAl), tantalumaluminide (TaAl),hafniumaluminide (HfAl), or titanium aluminum carbide (TiAlC), but it is not limited thereto. For a PMOS transistor, the work function metal layer having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer and the low resistance metal layer, in which the material of the barrier layer may include titanium (Ti), titanium nitride (TiN), tantalum (Ta) or tantalum nitride (TaN). Furthermore, the material of the low-resistance metal layer may include copper (Cu), aluminum (Al), titanium aluminum (TiAl), cobalt tungsten phosphide (CoWP) or any combination thereof.

Next, an interlayer dielectric (ILD) layer 22, such as a lower ILD layer is formed on the substrate 12 to cover the MOS transistors 14, and contact plugs 24, 26 are formed in the ILD layer 22 to electrically connect the source/drain regions 20. In this embodiment, the formation of the contact plugs 24, 26 could be accomplished by first performing a photo-etching process to remove part of the ILD layer 22 to form contact holes (not shown). Next, a barrier layer (not shown) and a metal layer (not shown) are formed into the contact holes, and a planarizing process such as chemical mechanical polishing (CMP) process is conducted to remove part of the metal layer and part of the barrier layer to form contact plugs 24, 26. Preferably, the barrier layer could be selected from the group consisting of Ti, TiN, Ta, and TaN and the metal layer could be selected from the group consisting of W, Cu, Al, TiAl, and CoWP, but not limited thereto.

Next, a capacitor 28 is formed on the ILD layer 22 to electrically or physically connect to the contact plug 26 within the ILD layer 22. In this embodiment, the formation of the capacitor 28 could be accomplished by sequentially forming a first conductive layer (not shown), at least a dielectric layer (not shown), a second conductive layer (not shown), and a patterned hard mask 30 on the ILD layer 22, and then using the patterned hard mask 30 to remove part of the second conductive layer, part of the dielectric layer, and part of the first conductive layer at the same time to form a patterned second conductive layer, a patterned dielectric layer, and a patterned first conductive layer. Preferably, the edges of the patterned second conductive layer are aligned to the edges of the patterned dielectric layer and patterned first conductive layer, in which the patterned second conductive layer becomes a top electrode of the capacitor, the patterned dielectric layer becomes a capacitor dielectric layer 34, and the patterned first conductive layer becomes a bottom electrode 36 of the capacitor. It should be noted that even though the capacitor dielectric layer 34 in this embodiment is a multi-layered structure containing three dielectric layers, the number of the capacitor dielectric layer 34 is not limited to the ones disclosed in this embodiment. For instance, it would be desirable to form a capacitor dielectric layer 34 made of a single dielectric layer, dual dielectric layers, or even three or more dielectric layers, which are all within the scope of the present invention.

In this embodiment, the top electrode 32 and bottom electrode 36 could be made of same material or different material, and could both be selected from the group consisting of W, Ti, TiN, Ta, TaN, and Al. The capacitor dielectric layer 34 is preferably made of dielectric material having low leakage, such as a material selected from the group consisting of oxide-nitride-oxide (ONO), silicon nitride, silicon oxide, and silicon oxynitride.

According to an embodiment of the present invention, the capacitor dielectric layer 34 could also include a high-k dielectric layer having dielectric constant (k value) larger than 4. For instance, the high-k dielectric layer may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

Next, a treatment process is conducted to expose the top electrode 32 and bottom. electrode 36 to an oxygen-containing gas for forming a protective layer 38 on the surface of the sidewalls of the top electrode 32 and bottom electrode 36. In this embodiment, the oxygen-containing gas preferably includes N₂O, but not limited thereto, and the protective layer 38 preferably includes metal oxide that could be selected from the group consisting of TiOₓ, TiON, TaOₓ, and TaON. It should be noted that the treatment process conducted with oxygen-containing gas only reacts with metal material such as the top electrode 32 and bottom electrode 36, hence the protective layer 38 would only be formed on the sidewall surfaces of the top electrode 32 and bottom electrode 36 but not on the sidewall surfaces of the hard mask 30 and the capacitor dielectric layer 34. Moreover, since part of the top electrode 32 and bottom electrode 36 may be consumed during the treatment process, the surface of the resulting protective layer 38 would be aligned to the sidewall surface of the capacitor dielectric layer 34.

Next, a dielectric layer 40, such as an upper ILD layer is formed on the ILD layer 22 to cover the capacitor 28 entirely, and a contact plug 42 is formed in the dielectric layer 40 and hard mask 30 to electrically connect to the top electrode 32. The formation of the contact plug 42 could be accomplished by the same approach as the formation of contact plugs 24, 26 disclosed above. For instance, it would be desirable to first perform a photo-etching process to remove part of the dielectric layer 40 and part of the hard mask 30 to form a contact hole (not shown). Next, a barrier layer (not shown) and a metal layer (not shown) are formed into the contact hole, and a planarizing process such as chemical mechanical polishing (CMP) process is conducted to remove part of the metal layer and part of the barrier layer to form a contact plug 42. Preferably, the barrier layer could be selected from the group consisting of Ti, TiN, Ta, and TaN and the metal layer could be selected from the group consisting of W, Cu, Al, TiAl, and CoWP, but not limited thereto. This completes the fabrication of a semiconductor device according to a preferred embodiment of the present invention. Next, additional inter-metal dielectric (IMD) layer could be formed on the dielectric layer 40 and metal interconnective process could be conducted to form metal interconnections within the IMD layer.

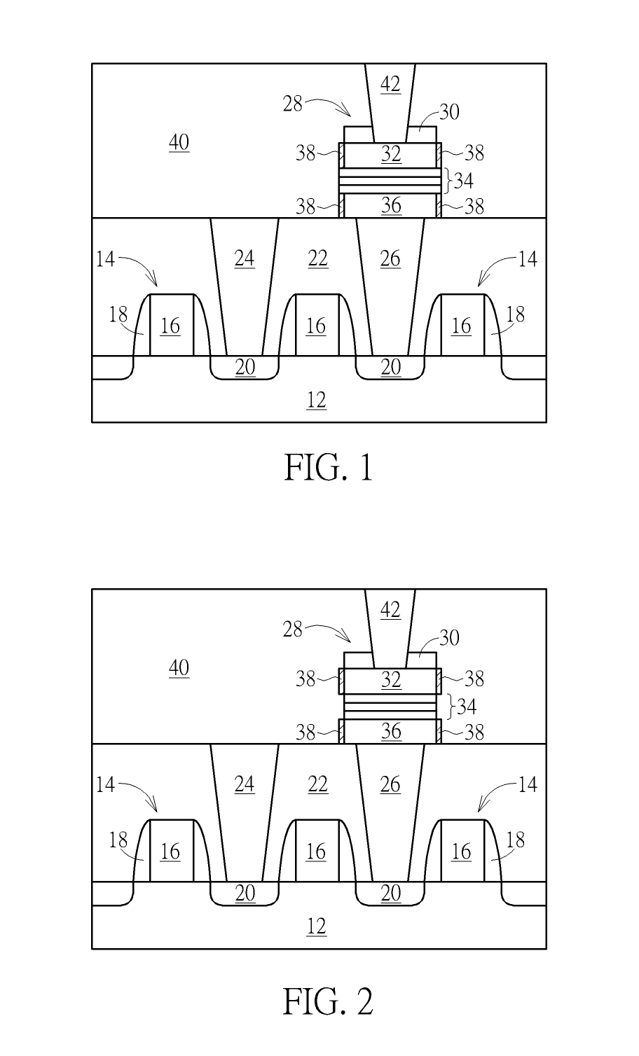

Referring to FIG. 2, FIG. 2 illustrates a structural view of a semiconductor device according to an embodiment of the present invention. As shown in FIG. 2, in contrast to the surface of protective layer 38 being aligned to the sidewall surface of the capacitor dielectric layer 34 as disclosed in FIG. 1, it would be desirable to adjust the flow rate and parameters of the gas provided during the treatment process so that the protective layer 38 could be formed directly on the surfaces of the top electrode 32 and bottom electrode 36 without consuming any of the top electrode 32 and bottom electrode 36. In other words, the protective layer 38 is formed on the surfaces of the sidewalls of top electrode 32 and bottom electrode 36 while the sidewall surfaces of top electrode 32 and bottom electrode 36 are aligned with the sidewall of the capacitor dielectric layer 34.

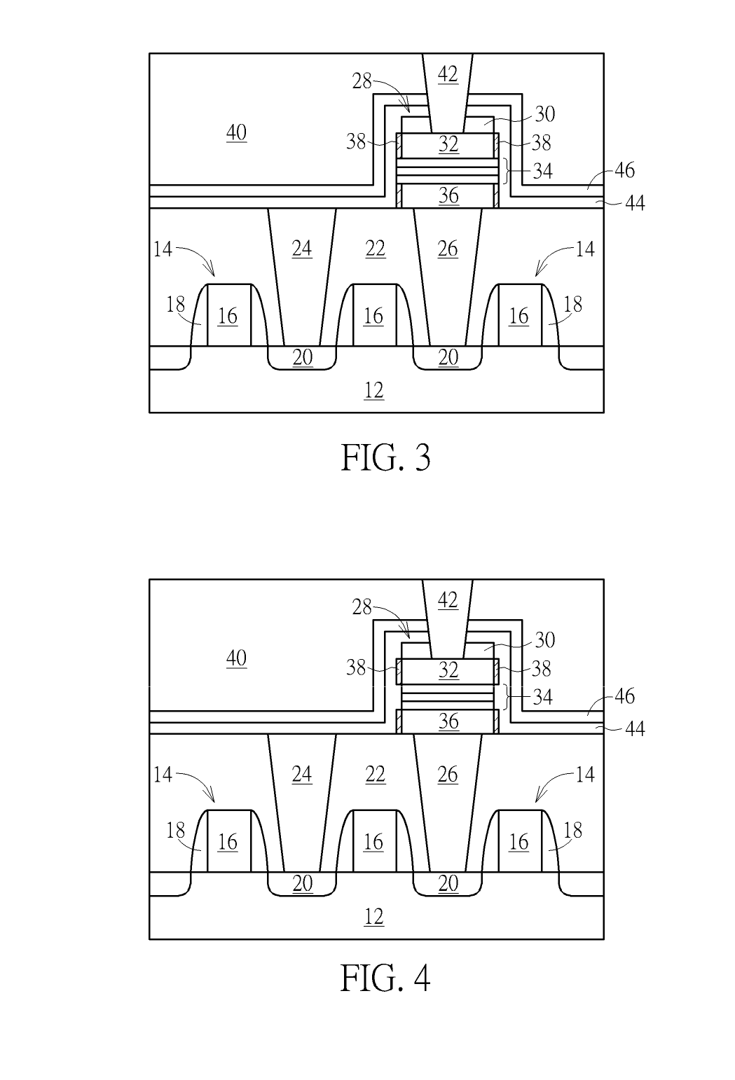

Referring to FIG. 3, FIG. 3 illustrates a structural view of a semiconductor device according to an embodiment of the present invention. As shown in FIG. 3, it would be desirable to sequentially form a first cap layer 44 and a second cap layer 46 on the ILD layer 22 and capacitor 28 right after the capacitor 28 is formed, form the dielectric layer 40 on the second cap layer 46, and then form contact plug 42 through the dielectric layer 40, second cap layer 46, first cap layer 44, and hard mask 30 to electrically connect to the top electrode 32. In this embodiment, the first cap layer 44 is preferably used as a buffer layer while the second cap layer 46 could be used as an etching stop layer. The first cap layer 44 and second cap layer 46 could be made of same material or different material, and the two cap layers 44 and 46 could be made of material including but not limited to for example, silicon nitride, silicon oxynitride, silicon carbon nitride, or combination thereof.

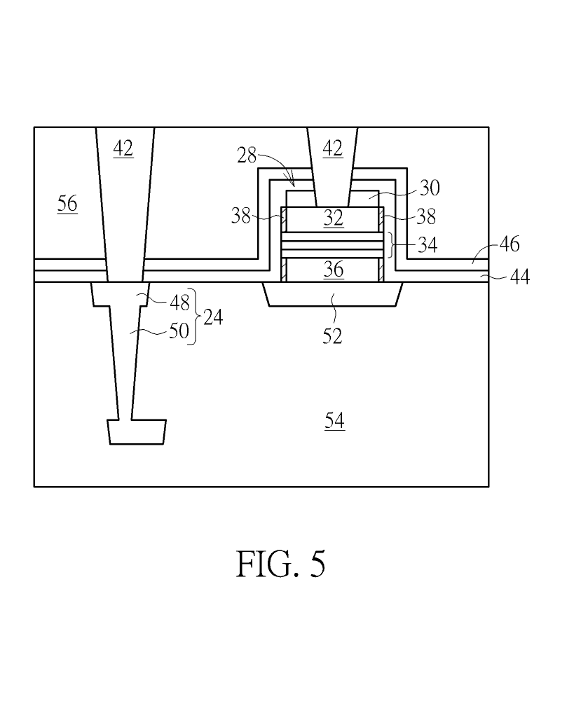

Referring to FIG. 4, FIG. 4 illustrates a structural view of a semiconductor device according to an embodiment of the present invention. As shown in FIG. 4, it would be desirable to first form a protective layer 38 on the sidewalls of top electrode 32 and bottom electrode 36 in the manner disclosed in FIG. 2, such as the surface of the protective layer 38 not being aligned to the sidewall surface of the capacitor dielectric layer 34. Next, a first cap layer 44, a second cap layer 46, and a dielectric layer 40 are formed on the ILD layer 22, and contact plug 42 is formed through the dielectric layer 40, second cap layer 46, first cap layer 44, and hard mask 30 to electrically connect to the top electrode 32.

Referring to FIG. 5, FIG. 5 illustrates a structural view of a semiconductor device according to an embodiment of the present invention. As shown in FIG. 5, it would be desirable to first form contact plug 24 consisting of trench conductor 48 and via conductor 50 along with conductive wire 52 within a IMD layer 54 above a ILD layer, and then form a MIM capacitor 28, first cap layer 44, second cap layer 46, dielectric layer 56, and contact plugs 42 electrically connected to the contact plug 24 and top electrode 32 respectively. Preferably, the conductive wire 52 contacting the bottom electrode 36 could be connected to transistors on other regions of the substrate 12 through redistribution method.

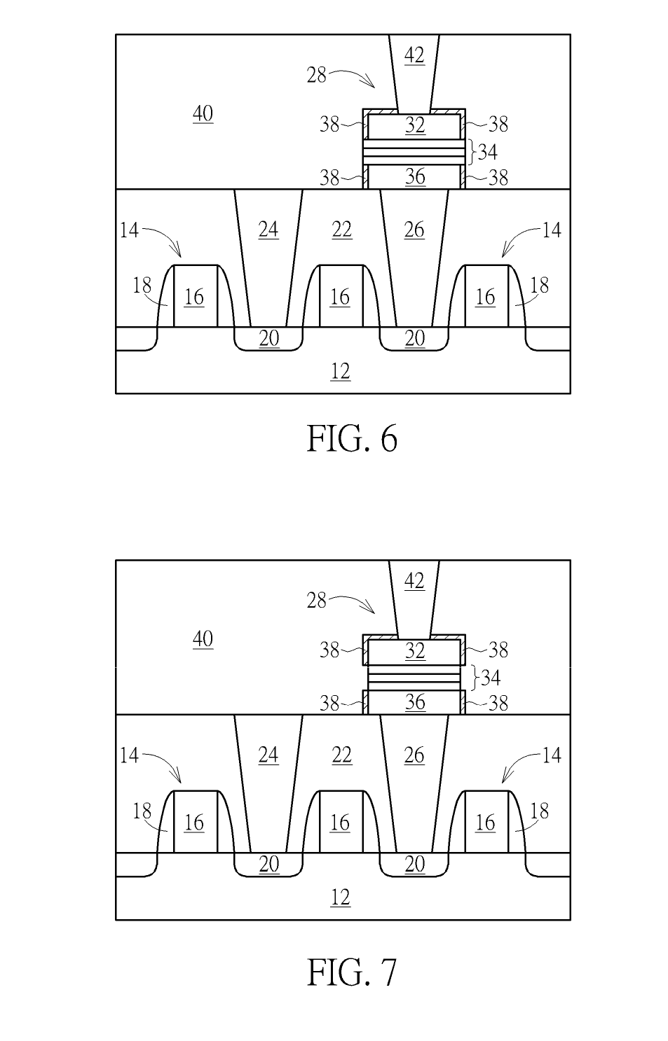

Referring to FIG. 6, FIG. 6 illustrates a structural view of a semiconductor device according to an embodiment of the present invention. As shown in FIG. 6, it would be desirable to not form any hard mask 30 after the bottom electrode 36, capacitor dielectric layer 34, and top electrode 32 are formed, or completely remove the patterned hard mask 30 after conductive layers are patterned to form the capacitor 28, and then performing the aforementioned treatment process to form the protective layer under the without the presence of any hard mask. In this instance, the protective layer 38 would be formed not only on the sidewall surfaces of the top electrode 32 and bottom electrode 36 but also on the top surface of the top electrode 32.

Referring to FIG. 7, FIG. 7 illustrates a structural view of a semiconductor device according to an embodiment of the present invention. As shown in FIG. 7, it would be desirable to combine the embodiment from FIG. 6 by not forming any hard mask on top of the top electrode 32 and the embodiment from FIG. 2 by forming the protective layer 38 directly on the top electrode 32 and bottom electrode 36 without consuming any top electrode 32 and bottom electrode 36. In other words, the protective layer 38 is disposed on the top surface and sidewall surfaces of the top electrode 32 as well as the sidewall surfaces of the bottom electrode 36 while the surface of the protective layer 38 is aligned with the sidewalls of the capacitor dielectric layer 34.

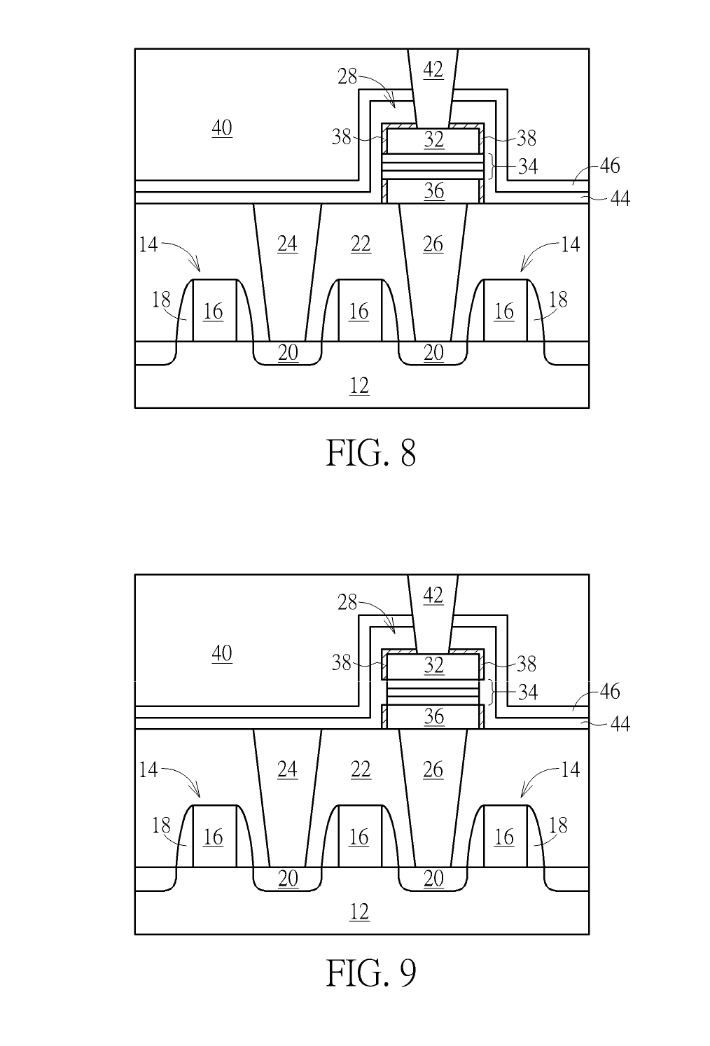

Referring to FIG. 8, FIG. 8 illustrates a structural view of a semiconductor device according to an embodiment of the present invention. As shown in FIG. 8, it would be desirable to combine the embodiment from FIG. 6 by not forming any hard mask on top of the top electrode 32 and the embodiment from FIG. 3 by forming a first cap layer 44 and second cap layer 46 on the ILD layer 22 and capacitor 28 after the capacitor 28 is formed.

Referring to FIG. 9, FIG. 9 illustrates a structural view of a semiconductor device according to an embodiment of the present invention. As shown in FIG. 9, it would be desirable to not only follow the embodiment from FIG. 7 by not forming any hard mask on top of the top electrode 32 and forming the protective layer 38 on the top surface and sidewalls of the top electrode 32 and sidewalls of the bottom electrode 36, but also follow the embodiment from either FIG. 3 or FIG. 4 by forming a first cap layer 44 and second cap layer 44 on the ILD layer 22 and capacitor 28 after the capacitor 28 is formed.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating semiconductor device, comprising:
providing a substrate;
forming a capacitor on the substrate and a hard mask on the capacitor, wherein the capacitor comprises a bottom electrode, a capacitor dielectric layer, and a top electrode; and
forming a protective layer on the sidewalls of the top electrode and the bottom electrode and directly contacting a top surface of the top electrode, wherein the protective layer comprises metal oxide.

2. The method of claim 1, further comprising:
forming an interlayer dielectric (ILD) layer on the substrate;
forming a first contact plug in the ILD layer;
forming the capacitor on the ILD layer, wherein the bottom electrode contacts the first contact plug; and
performing a treatment process to form the protective layer.

3. The method of claim 2, wherein the treatment process comprises exposing the sidewalls of the top electrode and the bottom electrode to an oxygen-containing gas.

4. The method of claim 2, further comprising:
forming a first cap layer on the ILD layer and the capacitor after forming the protective layer;
forming a dielectric layer on the first cap layer; and
forming a second contact plug in the dielectric layer and the first cap layer to electrically connect the top electrode.

5. The method of claim 4, further comprising forming a second cap layer on the first cap layer before forming the dielectric layer.

6. The method of claim 1, wherein the protective layer is selected from the group consisting of TiOₓ, TiON, TaOₓ, and TaON.

7. A semiconductor device, comprising:
a capacitor on a substrate, wherein the capacitor comprises a bottom electrode, a capacitor dielectric layer, and a top electrode;
a hard mask on the capacitor; and
a protective layer on the sidewalls of the top electrode and the bottom electrode and directly contacting a top surface of the top electrode, wherein the protective layer comprises metal oxide.

8. The semiconductor device of claim 7, further comprising:
an interlayer dielectric (ILD) layer on the substrate;
a first contact plug in the ILD layer;
the capacitor on the ILD layer, wherein the bottom electrode contacts the first contact plug.

9. The semiconductor device of claim 8, further comprising:
a first cap layer on the ILD layer and the capacitor;
a dielectric layer on the first cap layer; and
a second contact plug in the dielectric layer and the first cap layer to electrically connect to the top electrode.

10. The semiconductor device of claim 9, further comprising:
a second cap layer between the first cap layer and the dielectric layer.

11. The semiconductor device of claim 7, wherein the protective layer is selected from the group consisting of TiOₓ, TiON, TaOₓ, and TaON.
